(19) United States
(12) Patent Application Publication
(10) Pub. No.: US 2026/0290753 A1
(43) Pub. Date: Sep. 24, 2026

(54) SUBSTRATE PROCESSING APPARATUS AND SUBSTRATE PROCESSING METHOD

(71) Applicant: Tokyo Electron Limited, Tokyo (JP)

(72) Inventors: Keiichi NAKAMOTO, Miyagi (JP); Toshikatsu TOBANA, Miyagi (JP); Takanori BANSE, Miyagi (JP)

(73) Assignee: Tokyo Electron Limited, Tokyo (JP)

(21) Appl. No.: 19/677,120

(22) Filed: May 14, 2026

Related U.S. Application Data
(63) Continuation of application No. PCT/JP2024/039684, filed on Nov. 7, 2024.

(30) Foreign Application Priority Data
Nov. 21, 2023 (JP) 2023-197225

(51) Int. Cl. H01J 37/32

(52) U.S. Cl. CPC H01J 37/32174; H01J 37/32091; H01J 37/32669; H01J 37/32825; H01J 2237/332; H01J 2237/334

(57) ABSTRACT

A substrate processing apparatus includes a plasma processing chamber adjusted to a pressure within a range of 1 mTorr to 20 mTorr; a substrate support including a lower electrode, the substrate support to support a substrate; an upper electrode located above the substrate support; an electromagnet having at least two annular coils arranged concentrically; a first RF power supply to supply a source RF signal having a first RF frequency to the upper electrode; a second RF power supply to supply a bias RF signal having a second RF frequency to the lower electrode; and controller circuitry to control the substrate processing apparatus to repeat supply the source RF signal to the upper electrode to generate plasma in the plasma processing chamber in a state in which a magnetic field is generated by the electromagnet in the plasma processing chamber and deposit a deposit on the substrate.

### CROSS-REFERENCE TO RELATED APPLICATIONS

This application is a continuation application of International Application No. PCT/JP2024/039684, filed Nov. 7, 2024, which claims priority to Japanese Patent Application No. 2023-197225 filed Nov. 21, 2023. The contents of these applications are incorporated herein by reference in their entirety.

### BACKGROUND

### Field

The present disclosure relates to a substrate processing apparatus and a substrate processing method.

### Background Art

Japanese Unexamined Patent Application Publication No. 2021-150418 discloses a substrate processing method for a substrate processing apparatus, the substrate processing method including:
(a) supplying, into a processing container in which a stage on which a processing target including a first region composed of silicon oxide is placed is disposed, a process gas containing a fluorocarbon and a rare gas;
(b) performing plasma processing on the processing target with first plasma of the process gas generated under first plasma generation conditions;
(c) performing plasma processing on the processing target, on which a bias potential has been generated, with second plasma of the process gas generated under second plasma generation conditions different from the first plasma generation conditions; and
(d) repeating (b) and (c).

### SUMMARY

According to one aspect, a substrate processing apparatus is provided. The substrate processing apparatus includes: a plasma processing chamber adjusted to a pressure within a range of 1 mTorr to 20 mTorr; a substrate support located in the plasma processing chamber and including a lower electrode, the substrate support to support a substrate; an upper electrode located above the substrate support; an electromagnet having at least two annular coils arranged concentrically; a first RF power supply configured to supply a source RF signal having a first RF frequency to the upper electrode; a second RF power supply configured to supply a bias RF signal having a second RF frequency to the lower electrode; and controller circuitry configured to control the substrate processing apparatus to repeat

supply the source RF signal to the upper electrode to generate plasma in the plasma processing chamber in a state in which a magnetic field is generated by the electromagnet in the plasma processing chamber and deposit a deposit on the substrate; and supply the source RF signal to the upper electrode to generate plasma in the plasma processing chamber in a state in which a magnetic field is generated by the electromagnet in the plasma processing chamber and etch the substrate. A power level of the source RF signal in the etching the substrate is lower than a power level of the source RF signal in the depositing the deposit on the substrate.

### BRIEF DESCRIPTION OF THE DRAWINGS

The scope of the present disclosure is best understood from the following detailed description of exemplary embodiments when read in conjunction with the accompanying drawings.

FIG. 1 is a diagram illustrating an example of a configuration of a capacitively coupled plasma processing apparatus.

FIG. 2 is a schematic diagram illustrating an example of a state of plasma in a state in which generation of a magnetic field by a magnetic field generator is stopped.

FIG. 3 is a schematic diagram illustrating an example of a state of plasma in a state in which a magnetic field is generated by a magnetic field generator.

FIG. 4 is a diagram illustrating an example of a time chart of an etching process.

FIG. 5A is a schematic cross-sectional view illustrating an example of a structure formed on a substrate.

FIG. 5B is a schematic cross-sectional view illustrating an example of a structure formed on a substrate.

FIG. 6A is a diagram illustrating an example of a range in which plasma is stable.

FIG. 6B is a diagram illustrating an example of a range in which plasma is stable.

FIG. 6C is a diagram illustrating an example of a range in which plasma is stable.

FIG. 6D is a diagram illustrating an example of a range in which plasma is stable.

FIG. 7 is a graph illustrating an example of a magnetic field on a surface of a substrate W under respective conditions of coils.

FIG. 8 is a diagram illustrating an example of an effect of applying a magnetic field by a magnetic field generator.

FIG. 9A is a diagram illustrating an example of a configuration in which an electromagnet includes two coils and a magnetic field generated by the electromagnet.

FIG. 9B is a diagram illustrating an example of a configuration in which an electromagnet includes two coils and a magnetic field generated by the electromagnet.

FIG. 10A is a diagram illustrating an example of a configuration in which an electromagnet includes four coils and a magnetic field generated by the electromagnet.

FIG. 10B is a diagram illustrating an example of a configuration in which an electromagnet includes four coils and a magnetic field generated by the electromagnet.

### DETAILED DESCRIPTION

Hereinafter, various exemplary embodiments will be described in detail with reference to the drawings. In the drawings, the same or corresponding parts are denoted by the same reference numerals.

### Plasma Processing System

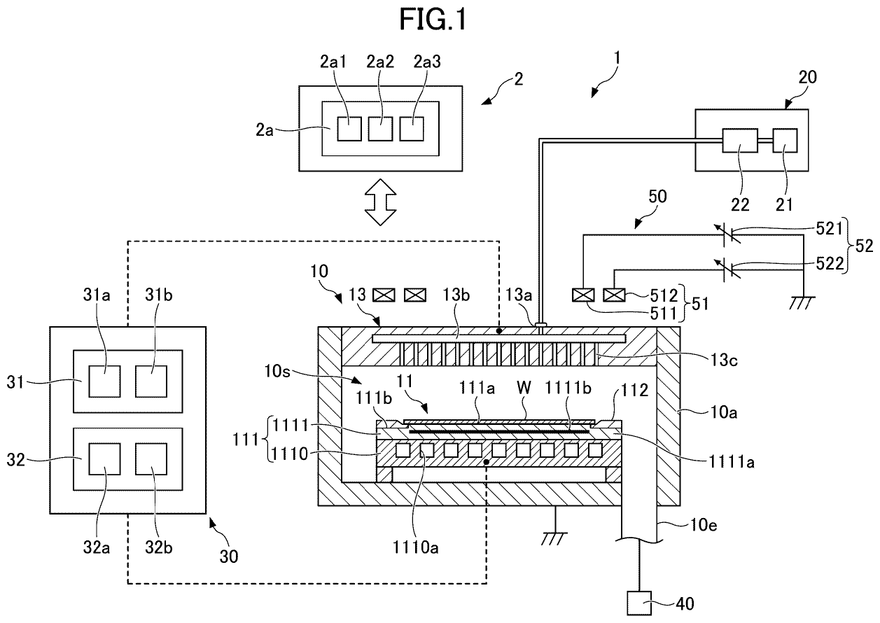

A configuration example of a plasma processing system will be described below. FIG. 1 is a diagram illustrating an example of a configuration of a capacitively coupled plasma processing apparatus (substrate processing apparatus) 1.

The plasma processing system includes a capacitively coupled plasma processing apparatus 1 and a controller 2 (herein “controller” means the same as “controller circuitry”). The capacitively coupled plasma processing apparatus 1 includes a plasma processing chamber 10, a gas supply 20, a power supply 30, and an exhaust system 40. The plasma processing apparatus 1 further includes a substrate support 11 and a gas introducer. The gas introducer is configured to introduce at least one process gas into the plasma processing chamber 10. The gas introducer includes a shower head 13. The substrate support 11 is disposed in the plasma processing chamber 10. The shower head 13 is disposed above the substrate support 11. In one embodiment, the shower head 13 forms at least a portion of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one process gas to the plasma processing space 10s and at least one gas exhaust port for exhausting gas from the plasma processing space 10s. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in plan view. The substrate W is disposed on the central region 111a of the main body 111, and the ring assembly 112 is disposed on the annular region 111b of the main body 111 so as to surround the substrate W disposed on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a further has the annular region 111b. Alternatively, another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to an RF (Radio Frequency) power supply 31 and/or a DC (Direct Current) power supply 32 described below may be disposed in the ceramic member 1111a. In this case, the at least one RF/DC electrode functions as a lower electrode. When a bias RF signal and/or a DC signal described below is supplied to the at least one RF/DC electrode, the RF/DC electrode is also referred to as a bias electrode. The conductive member of the base 1110 and the at least one RF/DC electrode may function as a plurality of lower electrodes. Alternatively, the electrostatic electrode 1111b may function as a lower electrode. Accordingly, the substrate support 11 includes at least one lower electrode.

The ring assembly 112 includes one or more annular members. In one embodiment, the one or more annular members include one or more edge rings and at least one cover ring. The edge ring is formed of a conductive material or an insulating material, and the cover ring is formed of an insulating material.

The substrate support 11 may further include a temperature control module configured to adjust at least one of the electrostatic chuck 1111, the ring assembly 112, or the substrate W to a target temperature. The temperature control module may include a heater, a heat transfer medium, a flow path 1110a, or a combination thereof. A heat transfer fluid such as brine or gas flows through the flow path 1110a. In one embodiment, the flow path 1110a is formed in the base 1110, and one or more heaters are disposed in the ceramic member 1111a of the electrostatic chuck 1111. The substrate support 11 may further include a heat transfer gas supply configured to supply a heat transfer gas to a gap between a rear surface of the substrate W and the central region 111a.

The shower head 13 is configured to introduce at least one process gas from the gas supply 20 into the plasma processing space 10s. The shower head 13 has at least one gas supply port 13a, at least one gas diffusion chamber 13b, and a plurality of gas introduction ports 13c. The process gas supplied to the gas supply port 13a passes through the gas diffusion chamber 13b and is introduced into the plasma processing space 10s through the plurality of gas introduction ports 13c. The shower head 13 includes at least one upper electrode. The gas introducer may further include one or more side gas injectors (SGIs) in addition to the shower head 13. In such a case, the one or more side gas injectors (SGIs) are attached to one or more openings formed in the sidewall 10a.

The gas supply 20 may include at least one gas source 21 and at least one flow controller 22. In one embodiment, the gas supply 20 is configured to supply at least one process gas from a corresponding gas source 21 to the shower head 13 via a corresponding flow controller 22. Each flow controller 22 may include, for example, a mass flow controller or a pressure-type flow controller. The gas supply 20 may further include one or more flow modulation devices configured to modulate or pulse a flow rate of the at least one process gas.

The power supply 30 includes an RF power supply 31 coupled to the plasma processing chamber 10 via at least one impedance matching circuit. The RF power supply 31 is configured to supply at least one RF signal (RF power) to at least one lower electrode and/or at least one upper electrode. As a result, a plasma is formed from at least one process gas supplied to the plasma processing space 10s. Accordingly, the RF power supply 31 may function as at least a part of a plasma generator configured to form plasma from one or more process gases in the plasma processing chamber 10. Further, by supplying a bias RF signal to at least one lower electrode, a bias potential is generated in the substrate W, and an ion component in the formed plasma can be drawn toward the substrate W.

In one embodiment, the RF power supply 31 includes a first RF generator 31a and a second RF generator 31b. The first RF generator 31a (first RF power supply) is coupled to at least one lower electrode and/or at least one upper electrode via at least one impedance matching circuit and is configured to generate a source RF signal (source RF power) for plasma generation. In one embodiment, the source RF signal has a first RF frequency within a range of 10 MHz to 150 MHz (e.g., 60 MHz). In one embodiment, the first RF generator 31a may be configured to generate a plurality of source RF signals having different frequencies. The generated one or more source RF signals are supplied to at least one lower electrode and/or at least one upper electrode.

The second RF generator 31b (second RF power supply) is coupled to at least one lower electrode via at least one impedance matching circuit and is configured to generate a bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a second RF frequency within a range of 100 kHz to 60 MHz (e.g., 12.88 MHz). In one embodiment, the second RF generator 31b may be configured to generate a plurality of bias RF signals having different frequencies. The generated one or more bias RF signals are supplied to at least one lower electrode. In various embodiments, at least one of the source RF signal or the bias RF signal may be pulsed.

The power supply 30 may further include a DC power supply 32 coupled to the plasma processing chamber 10. The DC power supply 32 includes a first DC generator 32a and a second DC generator 32b. In one embodiment, the first DC generator 32a is connected to at least one lower electrode and is configured to generate a first DC signal. The generated first DC signal is applied to at least one lower electrode. In one embodiment, the second DC generator 32b is connected to at least one upper electrode and is configured to generate a second DC signal. The generated second DC signal is applied to at least one upper electrode.

In various embodiments, at least one of the first DC signal or the second DC signal may be pulsed. In this case, a sequence of voltage pulses is applied to at least one lower electrode and/or at least one upper electrode. The voltage pulses may have a pulse waveform of a rectangular shape, a trapezoidal shape, a triangular shape, or a combination thereof. In one embodiment, a waveform generator for generating a sequence of voltage pulses from a DC signal is connected between the first DC generator 32a and at least one lower electrode. Accordingly, the first DC generator 32a and the waveform generator form a voltage pulse generator. When the second DC generator 32b and a waveform generator form a voltage pulse generator, the voltage pulse generator is connected to at least one upper electrode. The voltage pulses may have a positive polarity or a negative polarity. The sequence of voltage pulses may include one or more positive polarity voltage pulses and one or more negative polarity voltage pulses within one cycle. The first and second DC generators 32a and 32b may be provided in addition to the RF power supply 31, or the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure adjustment valve and a vacuum pump. The pressure in the plasma processing space 10s is adjusted by the pressure adjustment valve. The vacuum pump may include a turbo molecular pump, a dry pump, or a combination thereof.

The plasma processing apparatus 1 further includes a magnetic field generator 50 configured to generate a magnetic field in the plasma processing space 10s. The magnetic field generator 50 includes an electromagnet 51 and a power supply 52.

The electromagnet 51 includes a plurality of coils (two coils 511 and 512 in the example of FIG. 1). The coils 511 and 512 are annular coils disposed concentrically. The coil 512 is disposed radially outward of the coil 511. The coils 511 and 512 are disposed outside the plasma processing space 10s (outside the plasma processing chamber 10). The coils 511 and 512 are disposed above the upper electrode (shower head 13). The coils 511 and 512 are disposed concentrically with a central axis of the substrate support 11.

The power supply 52 supplies power to the electromagnet 51. The power supply 52 includes a power supply 521 configured to supply power to the coil 511 and a power supply 522 configured to supply power to the coil 512. The power supply 521 supplies power such that a current flows through the coil 511 in one direction. The power supply 522 supplies power such that a current flows through the coil 512 in a direction opposite to the one direction. As a result, a magnetic field generated by the coil 511 and a magnetic field generated by the coil 512 cancel each other on the substrate W, thereby reducing the magnetic field on the substrate W.

The number of annular coils included in the electromagnet 51 is not limited to two and may be greater than two. The electromagnet 51 may include an even number of coils, and coils adjacent in a radial direction may be configured such that currents flow in mutually opposite directions. The electromagnet 51 may include a plurality of pairs of coils in which currents flow in mutually opposite directions. In an electromagnet 51 having a plurality of coils, a number of coils through which current flows in one direction and a number of coils through which current flows in a direction opposite to the one direction may be equal. The electromagnet 51 may include an odd number of coils, and coils adjacent in the radial direction may be configured such that currents flow in mutually opposite directions. Although the plurality of coils have been described as being disposed at the same height, the coils are not limited thereto and may be disposed at different positions in a height direction.

The controller 2 processes computer-executable instructions for causing the plasma processing apparatus 1 to perform various processes described in the present disclosure. The controller 2 may be configured to control respective elements of the plasma processing apparatus 1 to perform the various processes described herein. In one embodiment, a part or all of the controller 2 may be included in the plasma processing apparatus 1. The controller 2 may include a processor 2a1, a storage 2a2, and a communication interface 2a3. The controller 2 may be implemented by, for example, a computer 2a. The processor 2a1 may be configured to read a program from the storage 2a2 and perform various control operations by executing the read program. The program may be stored in advance in the storage 2a2 or may be acquired via a medium when necessary. The acquired program is stored in the storage 2a2 and read from the storage 2a2 and executed by the processor 2a1. The medium may be various storage media readable by the computer 2a or may be a communication line connected to the communication interface 2a3. The processor 2a1 may be a CPU (Central Processing Unit). The storage 2a2 may include RAM (Random Access Memory), ROM (Read Only Memory), HDD (Hard Disk Drive), SSD (Solid State Drive), or a combination thereof. The communication interface 2a3 may communicate with the plasma processing apparatus 1 via a communication line such as a LAN (Local Area Network). The controller/controller circuitry 2 can be programmable circuitry (e.g., embedded processor) or fixed circuitry (e.g., ASIC or PAL). In an exemplary embodiment, the controller/controller circuitry 2 can include one or more programmable processors/controllers.

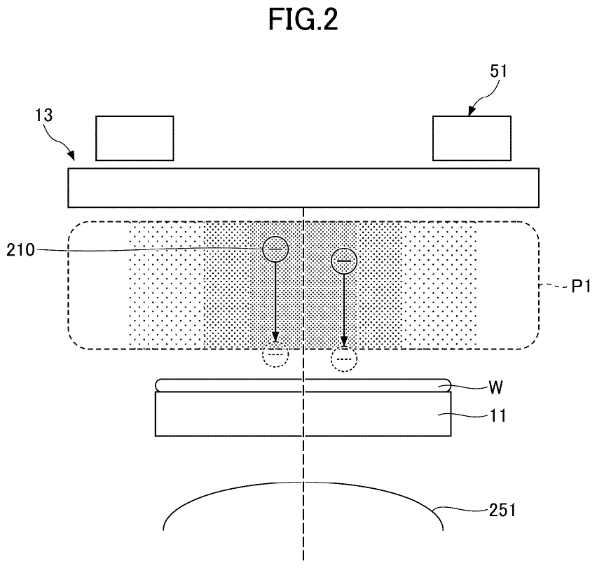

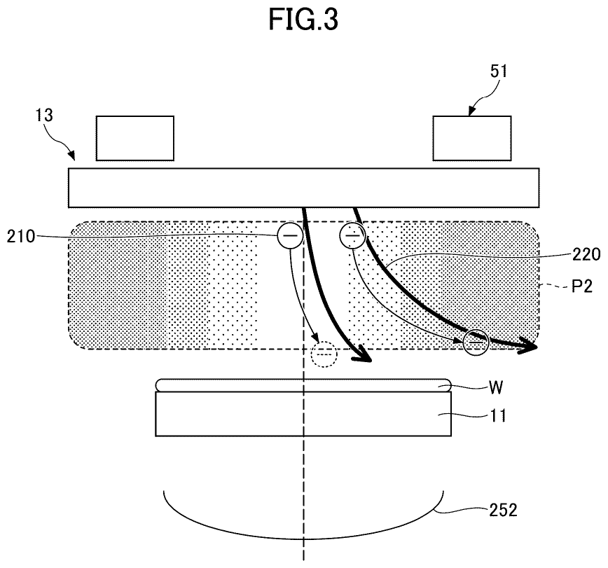

Next, a method for controlling plasma generated in the plasma processing space 10s by the magnetic field generator 50 will be described with reference to FIGS. 2 and 3.

FIG. 2 is a schematic diagram illustrating an example of a state of plasma P1 when generation of the magnetic field by the magnetic field generator 50 is stopped.

Here, plasma P1 is generated between the upper electrode (shower head 13) and the lower electrode (substrate support 11) by supplying a source RF signal (source RF power) to the upper electrode (shower head 13). In plasma P1, the electron density near the center E_{Center} is higher than the electron density near the outer periphery E_{Edge} (E_{Center}>E_{Edge}). In FIG. 2, the density distribution of electrons is schematically illustrated by shading density of dot hatching.

When performing an etching process on the substrate W, a tendency 251 of the etching rate is schematically illustrated. The tendency 251 of the etching rate correlates with the electron density in plasma P1, and illustrates a tendency for the etching rate to be higher near the center of the substrate W and lower near the outer peripheral of the substrate W.

Further, charged particles 210 (e.g., electrons) in plasma P1 move toward the lower electrode by a bias RF signal (bias RF power) supplied to the lower electrode. When the charged particles 210 reach the sheath, the charged particles 210 disappear (illustrated by dashed lines in FIG. 2).

FIG. 3 is a schematic diagram illustrating an example of a state of plasma P2 when a magnetic field is generated by the magnetic field generator 50.

Here, plasma P2 is generated between the upper electrode (shower head 13) and the lower electrode (substrate support 11) by supplying a source RF signal (source RF power) to the upper electrode (shower head 13).

An example of magnetic flux 220 generated by the electromagnet 51 is indicated by solid arrows. As illustrated in FIG. 3, the magnetic flux 220 has a direction toward the outer periphery. Charged particles 210 in plasma P2 move toward the outer periphery due to the Lorentz force of the magnetic flux 220 having a horizontal component. As a result, in plasma P2, the electron density near the outer periphery E_{Edge} is higher than the electron density near the center E_{Center} (E_{Center}<E_{Edge}). In FIG. 3, the density distribution of electrons is schematically illustrated by shading density of dot hatching.

When performing an etching process on the substrate W, a tendency 252 of the etching rate is schematically illustrated. The tendency 252 of the etching rate correlates with the electron density in plasma P2, and illustrates a tendency for the etching rate to be higher near the center of the substrate W and lower near the outer peripheral of the substrate W.

Further, charged particles 210 (e.g., electrons) in plasma P2 move toward the lower electrode by a bias RF signal (bias RF power) supplied to the lower electrode. When the charged particles 210 reach the sheath, the charged particles 210 disappear (illustrated by dashed lines in FIG. 3). Here, when comparing FIG. 2 and FIG. 3, the moving distance until the charged particles 210 reach the sheath is longer in FIG. 3. In other words, disappearance of the charged particles 210 can be delayed.

With miniaturization of semiconductor devices formed on the substrate W, improvement in plasma uniformity has been preferred. In plasma etching processing, plasma generated in the plasma processing chamber 10 controlled to a low pressure (1 mTorr to 20 mTorr) has higher uniformity, and as a result, uniformity of the etching rate is improved.

On the other hand, under low pressure, since the density of gas molecules is low and collisions between gas molecules are reduced, it becomes difficult to maintain plasma. Further, with miniaturization of semiconductor devices formed on the substrate W, there is a limitation in increasing the strength of the source RF signal (source RF power) for generating plasma.

As illustrated in FIG. 3, by applying the magnetic field generated by the magnetic field generator 50, the charged particles 210 in the plasma P2 move along the magnetic flux 220. As a result, the travel distance until the charged particles 210 reach the sheath becomes longer. In other words, the probability that the charged particles 210 collide with other gas molecules or the like before reaching the sheath increases, and the density of the plasma increases. Accordingly, the plasma P2 illustrated in FIG. 3 can suppress deactivation of the plasma even under a low pressure, as compared with the plasma P1 illustrated in FIG. 2.

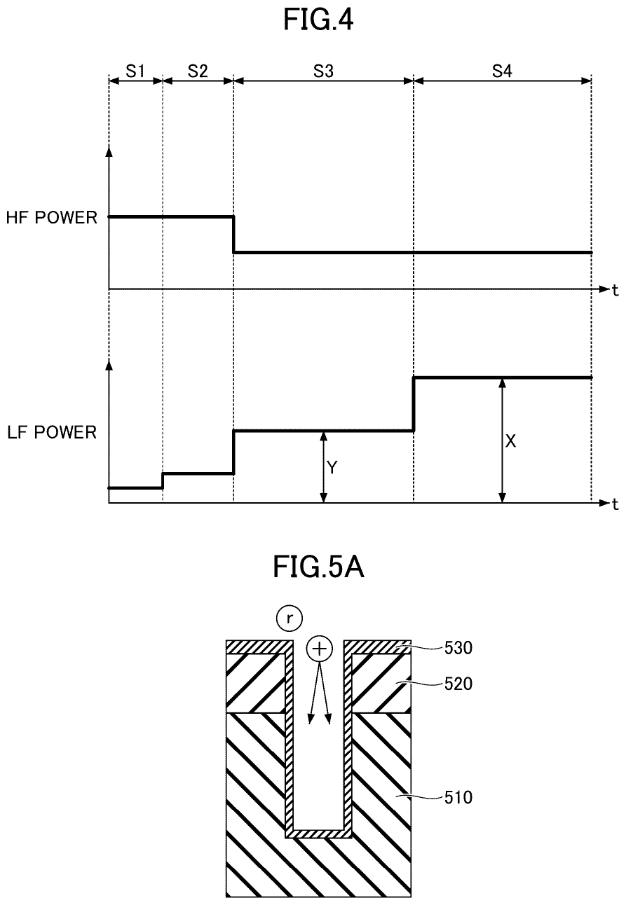

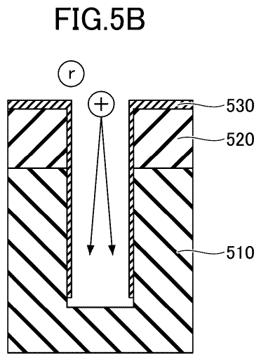

Next, an example of the etching processing will be described with reference to FIG. 4 and FIGS. 5A to 5B. FIG. 4 is a diagram illustrating an example of a time chart of the etching processing. FIGS. 5A to 5B are schematic cross-sectional views illustrating an example of a structure formed on the substrate W. In FIG. 4, the upper stage indicates power of the source RF signal (source RF power) (hereinafter, also referred to as HF power), and the lower stage indicates power of the bias RF signal (bias RF power) (hereinafter, also referred to as LF power).

First, the controller 2 controls a transfer device to transfer the substrate W to the substrate support 11 and to cause the substrate support 11 to support the substrate W. Next, the controller 2 controls the exhaust system 40 to control the inside of the plasma processing chamber 10 to a predetermined pressure. Here, the predetermined pressure is within a range of 1 mTorr to 20 mTorr. The predetermined pressure is preferably within a range of 1 mTorr to 10 mTorr, and more preferably within a range of 3 mTorr to 8 mTorr. Next, the controller 2 controls the gas supply 20 to supply a processing gas. The processing gas includes, for example, C₄F₆, Ar, and O₂. Further, the controller 2 controls the power supply 52 to supply power from the power supply 52 to the electromagnet 51 (coils 511 and 512), thereby generating a magnetic field in the electromagnet 51.

Next, the controller 2 controls the power supply 30 to supply the source RF signal (source RF power) to the upper electrode and to supply the bias RF signal (bias RF power) to the lower electrode, thereby performing etching processing on the substrate W.

Here, the etching processing repeats a step (S1, S2) of depositing a deposit on the substrate W and a step (S3, S4) of etching the substrate W.

As illustrated in FIG. 4, the HF power in the step (S1, S2) of depositing the deposit is greater than the HF power in the step (S3, S4) of etching. Further, the LF power in the step (S1, S2) of depositing the deposit is smaller than the LF power in the step (S3, S4) of etching. As a result, on the surface of the substrate W, the amount of deposition of the deposit becomes dominant over the etching amount.

As illustrated in FIG. 5A, on the substrate W, an etching target film 510 (e.g., SiO₂) and a mask 520 (e.g., SiN) are laminated, and recesses such as trenches and holes are formed in the etching target film 510 from the mask 520. In the step (S1, S2) of depositing the deposit, a deposit 530 is deposited on the surface of the substrate W (herein “film” means the same as “layer”).

Further, as illustrated in FIG. 4, the HF power in the step (S3, S4) of etching is smaller than the HF power in the step (S1, S2) of depositing the deposit. Further, the LF power in the step (S3, S4) of etching is greater than the LF power in the step (S1, S2) of depositing the deposit. As a result, on the surface of the substrate W, the etching amount becomes dominant over the amount of deposition of the deposit 530.

As illustrated in FIG. 5B, in the step (S3, S4) of etching, a bottom portion of the recess of the etching target film 510 is etched.

Each of steps S1 to S4 will be further described with reference to FIG. 4. The step (S1, S2) of depositing the deposit includes a first period (S1) and a second period (S2). The step (S3, S4) of etching includes a third period (S3) and a fourth period (S4).

In step S1, during the first period, HF power at a first power level is supplied to the upper electrode, and LF power at a fifth power level is supplied to the lower electrode. Here, the first power level is within a range of 50 W to 200 W. The fifth power level is within a range of 0 W to 50 W. Here, by increasing the HF power, the amount of deposition of the deposit 530 becomes dominant over the etching amount on the surface of the substrate W. As a result, the deposit 530 containing CFx is deposited on an upper surface of the mask 520 and on sidewalls of recesses formed in the mask 520 and the etching target film 510.

In step S2, during the second period, HF power at a second power level is supplied to the upper electrode, and LF power at a sixth power level is supplied to the lower electrode. Here, the second power level is within a range of 50 W to 200 W. The second power level is equal to the first power level. The sixth power level is higher than the fifth power level. Here, by increasing the HF power, the amount of deposition of the deposit 530 becomes dominant over the etching amount on the surface of the substrate W. Further, by increasing the LF power, ions are drawn into the recess, and the deposit 530 at a bottom portion of the recess is etched.

In step S3, during the third period, HF power at a third power level is supplied to the upper electrode, and LF power at a seventh power level is supplied to the lower electrode. Here, the third power level is within a range of 50 W to 200 W. The third power level is lower than the first power level and the second power level. The seventh power level is higher than the sixth power level. Here, by decreasing the HF power, the etching amount becomes dominant over the amount of deposition of the deposit 530 on the surface of the substrate W. Further, by further increasing the LF power, ions are drawn into the recess, and a bottom portion of the recess of the etching target film 510 is etched.

In step S4, during the fourth period, HF power at a fourth power level is supplied to the upper electrode, and LF power at an eighth power level is supplied to the lower electrode. Here, the fourth power level is within a range of 50 W to 200 W. The fourth power level is lower than the first power level and the second power level, and is equal to the third power level. The eighth power level is higher than the seventh power level. Here, by decreasing the HF power, the etching amount becomes dominant over the amount of deposition of the deposit 530 on the surface of the substrate W. Further, by further increasing the LF power, ions are drawn into the recess, and the bottom portion of the recess of the etching target film 510 is etched.

As described above, by defining the processing of steps S1 to S4 as one cycle and repeating this cycle, the mask 520 and the sidewalls of the recess are protected by the deposit 530 while etching the bottom portion of the recess of the etching target film 510.

Further, in the step (S3, S4) of etching, even when the HF power is reduced, by applying the magnetic field generated by the magnetic field generator 50, deactivation of the plasma can be suppressed even under a low pressure. Further, plasma generated in the plasma processing chamber 10 controlled to a low pressure has high uniformity, and as a result, uniformity of the etching rate is improved.

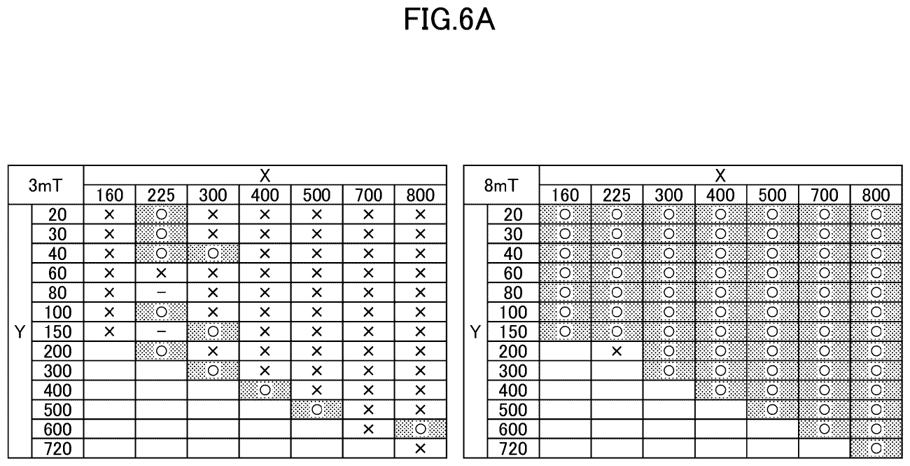

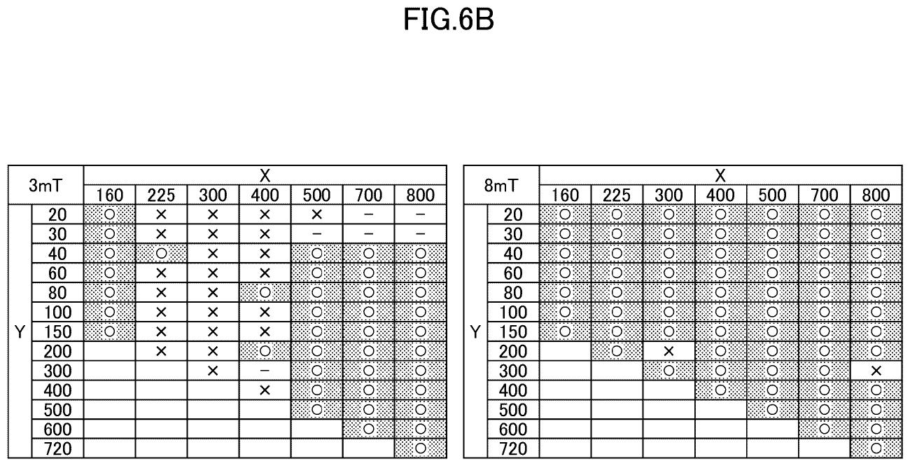

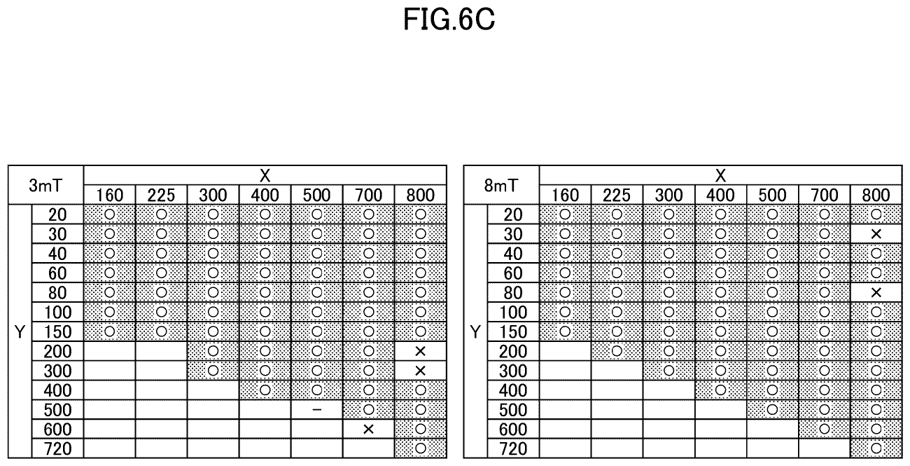

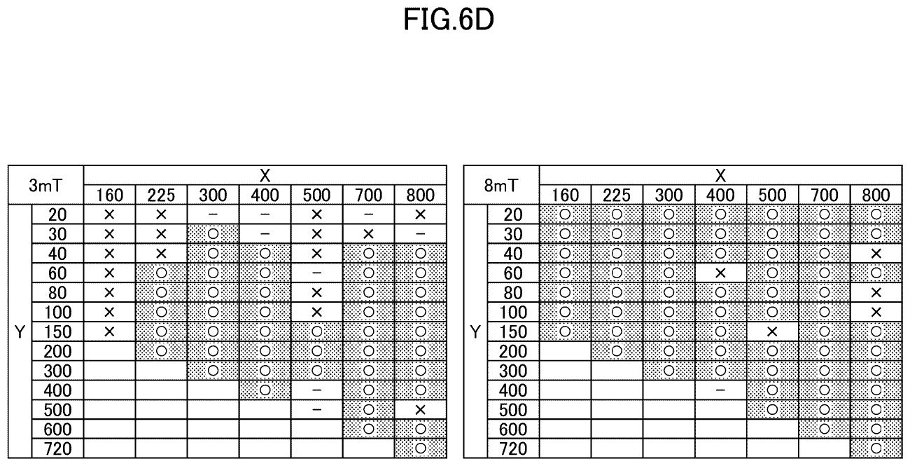

Next, an example in which plasma is stably generated by applying the magnetic field generated by the magnetic field generator 50 will be described with reference to FIGS. 6A to 6D. FIGS. 6A to 6D are diagrams illustrating an example of a range in which plasma is stabilized. FIG. 6A illustrates a case in which the coils 511 and 512 do not generate a magnetic field. FIG. 6B illustrates a case in which the coil 511 generates a magnetic field of −18 [G] and the coil 512 generates a magnetic field of +18 [G]. FIG. 6C illustrates a case in which the coil 511 generates a magnetic field of −18 [G] and the coil 512 generates a magnetic field of +36 [G]. FIG. 6D illustrates a case in which the coil 511 generates a magnetic field of −36 [G] and the coil 512 generates a magnetic field of +36 [G]. Further, the left table illustrates a case in which a pressure in the plasma processing chamber 10 is 3 mTorr, and the right table illustrates a case in which the pressure in the plasma processing chamber 10 is 8 mTorr. X represents the eighth power level, and Y represents the seventh power level.

Here, experiments were conducted to confirm whether plasma was stably generated, with the first power level and the second power level set to 100 [W], the third power level and the fourth power level set to 50 [W], the fifth power level set to 0 [W], the sixth power level set to 40 [W], the seventh power level set to Y [W], and the eighth power level set to X [W].

A case in which plasma was stably generated is marked with “∘”, and a case in which plasma was not stably generated is marked with “−” or “×”. Further, a case in which plasma was stably generated is explicitly indicated by shading.

At 8 mTorr, as illustrated in FIGS. 6A to 6D, plasma was stably generated in many regions of combinations of X and Y.

On the other hand, at 3 mTorr, as illustrated in FIG. 6A in a case in which no magnetic field was generated, plasma was not stably generated in many regions of combinations of X and Y.

In contrast, at 3 mTorr, as illustrated in FIGS. 6B to 6D in cases in which a magnetic field was generated, regions of combinations of X and Y in which plasma was stably generated increased as compared with FIG. 6A.

As described above, by applying the magnetic field generated by the magnetic field generator 50 into the plasma processing chamber 10, a range in which plasma can be stably generated even under a low pressure (e.g., 3 mTorr) is expanded.

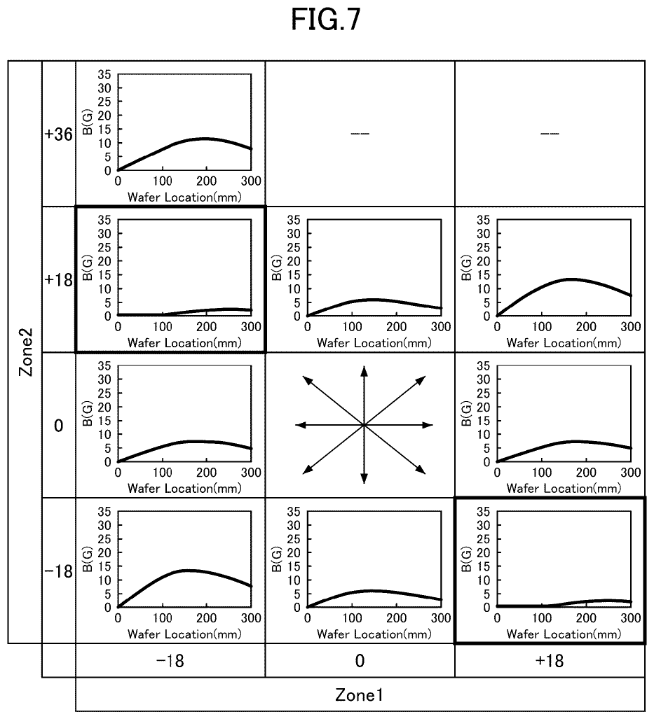

Next, a relationship between the magnetic fields generated by the coils 511 and 512 and the magnetic field on the surface of the substrate W will be described with reference to FIG. 7. FIG. 7 is a graph illustrating an example of a magnetic field on the surface of the substrate W under respective conditions of the coils 511 and 512. Here, Zone1 indicates a magnetic field generated by the coil 511. Zone2 indicates a magnetic field generated by the coil 512. Simulation results are shown for a radial position (Wafer Location) from a center of the substrate W and a magnetic field B at that position, with combinations in which the magnetic field generated by the coil 511 is −18 [G], 0 [G], or +18 [G], and the magnetic field generated by the coil 512 is −18 [G], 0 [G], +18 [G], or +36 [G]. A radius of the substrate W is 150 [mm].

As illustrated in FIG. 7, it is shown that, in combinations of (Zone1, Zone2) of (−18 [G], +18 [G]) and (+18 [G], −18 [G]), an influence of the magnetic field in a region of the substrate W is small. That is, when a direction of a current flowing through the coil 511 and a direction of a current flowing through the coil 512 are opposite to each other, the influence of the magnetic field in the region of the substrate W is small. Accordingly, the influence of the magnetic field on etching characteristics (etch rate and uniformity) of the substrate W can be suppressed.

In FIG. 7, a case in which the currents flowing through the coils 511 and 512 are controlled so as to reduce the influence of the magnetic field in the region of the substrate W has been described as an example; however, the present disclosure is not limited thereto. The currents flowing through the coils 511 and 512 may be controlled so as to adjust a density of plasma.

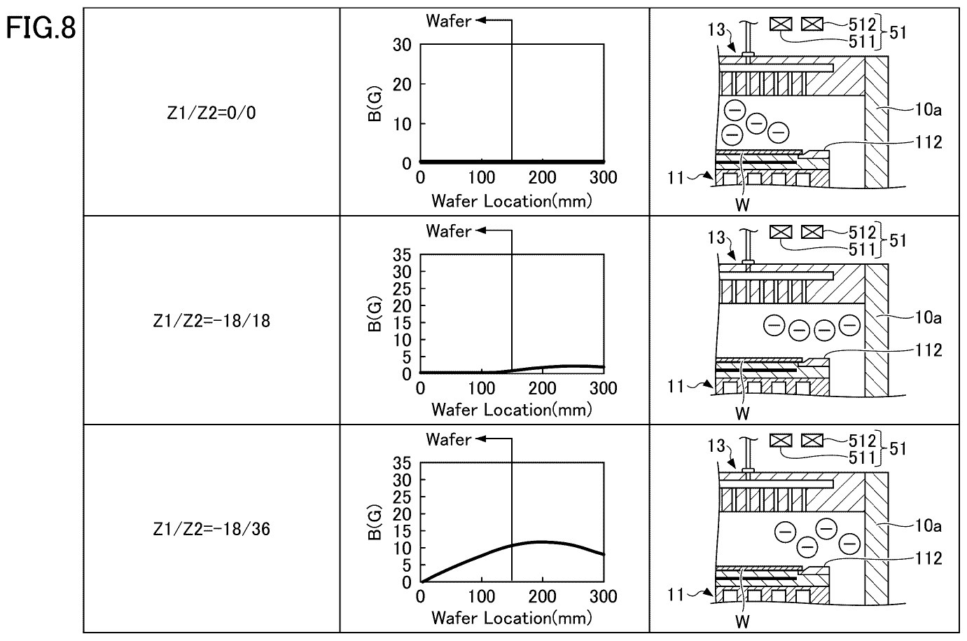

FIG. 8 is a diagram illustrating an example of an effect of applying the magnetic field generated by the magnetic field generator 50. Here, combinations of (Zone1, Zone2) of (0 [G], 0 [G]), (−18 [G], +18 [G]), and (−18 [G], +36 [G]) will be described as examples.

In (0 [G], 0 [G]), a magnetic field on the substrate support 11 is zero. Therefore, charged particles in the plasma processing chamber 10 increase near a center in a radial direction.

In (−18 [G], +18 [G]), a magnetic field on the substrate W is substantially zero, and the magnetic field increases outside the substrate W. Therefore, charged particles in the plasma processing chamber 10 increase near an outer periphery in the radial direction.

In (−18 [G], +36 [G]), the magnetic field increases near a ring assembly 112 (edge ring) from an outer edge of the substrate W. Therefore, charged particles in the plasma processing chamber 10 increase near an outer periphery in the radial direction.

As described above, by controlling the magnetic fields generated by the coils 511 and 512, a density of plasma in a radial direction can be adjusted.

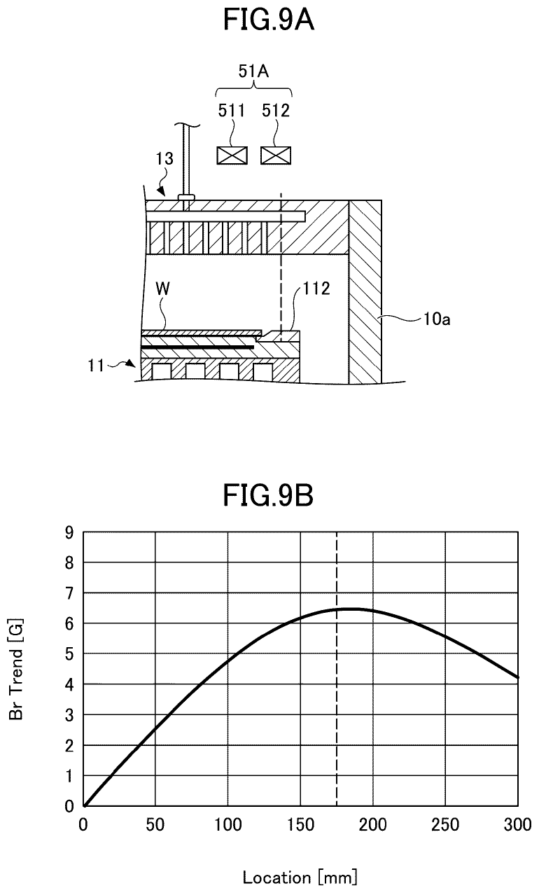

FIGS. 9A to 9B are diagrams illustrating a configuration in which an electromagnet 51A includes two coils 511 to 512, and an example of a magnetic field generated by the electromagnet 51A. FIG. 9A is a partially enlarged view of a substrate processing apparatus illustrating an example of arrangement of the coils 511 to 512. FIG. 9B illustrates simulation results of a radial position (Location) from a center of the substrate W and a magnetic field B at that position. A radius of the substrate W is 150 [mm]. In FIGS. 9A and 9B, a position at which the magnetic field B reaches a peak is indicated by a dashed line.

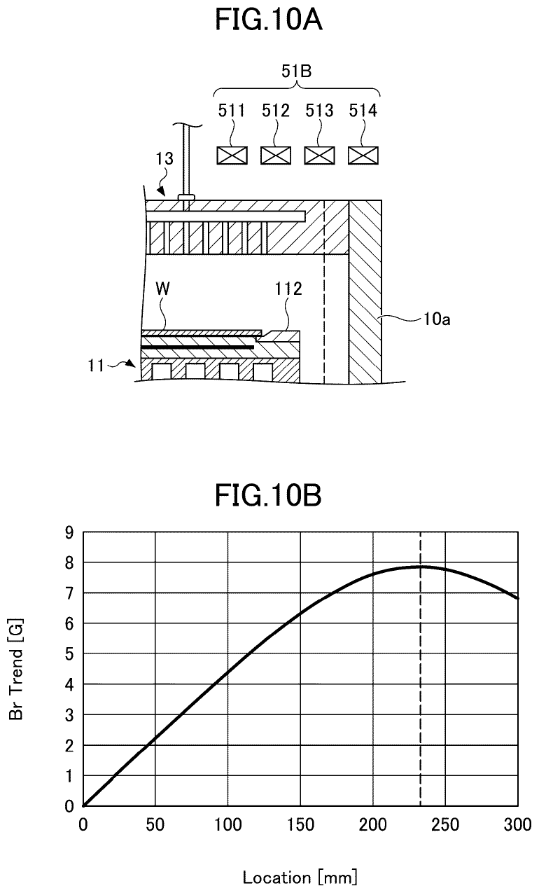

FIGS. 10A to 10B are diagrams illustrating a configuration in which an electromagnet 51B includes four coils 511 to 514, and an example of a magnetic field generated by the electromagnet 51B. FIG. 10A is a partially enlarged view of a substrate processing apparatus illustrating an example of arrangement of the coils 511 to 514. FIG. 10B illustrates simulation results of a radial position (Location) from a center of the substrate W and a magnetic field B at that position. A radius of the substrate W is 150 [mm]. In FIGS. 10A and 10B, a position at which the magnetic field B reaches a peak is indicated by a dashed line.

As illustrated by comparison of FIGS. 9A and 10A, in the configuration including four coils 511 to 514, the coils are disposed further outward in a radial direction as compared with the configuration including two coils 511 to 512. Accordingly, as illustrated by comparison of FIGS. 9B and 10B, in the configuration including four coils 511 to 514, a plasma density in a vicinity of the sidewall 10a can be increased as compared with the configuration including two coils 511 to 512.

As described above, by changing the number and positions of the coils of the electromagnet, a position at which plasma density becomes high can be adjusted.

The embodiments disclosed above include, for example, the following aspects.

### Clause 1

A substrate processing apparatus including:
a plasma processing chamber adjusted to a pressure within a range of 1 mTorr to 20 mTorr;
a substrate support disposed in the plasma processing chamber and including a lower electrode, the substrate support being configured to support a substrate;
an upper electrode disposed above the substrate support;
an electromagnet having at least two annular coils arranged concentrically;
a first RF power supply configured to supply a source RF signal having a first RF frequency to the upper electrode;
a second RF power supply configured to supply a bias RF signal having a second RF frequency to the lower electrode; and
a controller,
wherein the controller is configured to repeat
   supplying the source RF signal to the upper electrode to generate plasma in the plasma processing chamber in a state in which a magnetic field is generated by the electromagnet in the plasma processing chamber and depositing a deposit on the substrate, and
   supplying the source RF signal to the upper electrode to generate plasma in the plasma processing chamber in a state in which a magnetic field is generated by the electromagnet in the plasma processing chamber and etching the substrate, and
wherein a power level of the source RF signal in the step of etching the substrate is lower than a power level of the source RF signal in the step of depositing the deposit on the substrate.

### Clause 2

The substrate processing apparatus according to clause 1, wherein a power level of the bias RF signal in the step of etching the substrate is higher than a power level of the bias RF signal in the step of depositing the deposit on the substrate.

### Clause 3

The substrate processing apparatus according to clause 1 or 2, wherein
the step of depositing the deposit on the substrate includes a first period and a second period,
the step of etching the substrate includes a third period and a fourth period,
the power level of the source RF signal is a first power level in the first period, a second power level in the second period, a third power level in the third period, and a fourth power level in the fourth period, and
the power level of the bias RF signal is a fifth power level in the first period, a sixth power level in the second period, a seventh power level in the third period, and an eighth power level in the fourth period.

### Clause 4

The substrate processing apparatus according to any one of clauses 1 to 3, wherein
the second power level is equal to the first power level,
the third power level is lower than the second power level,
the fourth power level is equal to the third power level,
the sixth power level is higher than the fifth power level,
the seventh power level is higher than the sixth power level, and
the eighth power level is higher than the seventh power level.

### Clause 5

The substrate processing apparatus according to clause 4, wherein the fifth power level is 0 [W].

### Clause 6

The substrate processing apparatus according to any one of clauses 1 to 5, wherein currents flowing through radially adjacent coils of the electromagnet are in mutually opposite directions.

### Clause 7

The substrate processing apparatus according to any one of clauses 1 to 6, wherein the pressure in the plasma processing chamber is within a range of 1 mTorr to 10 mTorr.

### Clause 8

The substrate processing apparatus according to any one of clauses 1 to 6, wherein the pressure in the plasma processing chamber is within a range of 3 mTorr to 8 mTorr.

### Clause 9

A substrate processing method for a substrate processing apparatus, the substrate processing apparatus including a plasma processing chamber adjusted to a pressure within a range of 1 mTorr to 20 mTorr; a substrate support disposed in the plasma processing chamber and including a lower electrode, the substrate support being configured to support a substrate; an upper electrode disposed above the substrate support; an electromagnet having at least two annular coils arranged concentrically; a first RF power supply configured to supply a source RF signal having a first RF frequency to the upper electrode; and a second RF power supply configured to supply a bias RF signal having a second RF frequency to the lower electrode, the substrate processing method including:
repeating
   supplying the source RF signal to the upper electrode to generate plasma in the plasma processing chamber in a state in which a magnetic field is generated by the electromagnet in the plasma processing chamber and depositing a deposit on the substrate, and
   supplying the source RF signal to the upper electrode to generate plasma in the plasma processing chamber in a state in which a magnetic field is generated by the electromagnet in the plasma processing chamber and etching the substrate,
wherein a power level of the source RF signal in the step of etching the substrate is lower than a power level of the source RF signal in the step of depositing the deposit on the substrate.

According to one aspect, a substrate processing apparatus and a substrate processing method capable of stably forming a plasma under low pressure can be provided.

The configurations and the like described in the above embodiments are merely examples, and the present invention is not limited to the configurations described herein. These configurations may be modified without departing from the spirit of the present invention, and may be appropriately determined according to the application form.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

What is claimed is:

1. A substrate processing apparatus comprising:
a plasma processing chamber adjusted to a pressure within a range of 1 mTorr to 20 mTorr;
a substrate support located in the plasma processing chamber and including a lower electrode, the substrate support to support a substrate;
an upper electrode located above the substrate support;
an electromagnet having at least two annular coils arranged concentrically;
a first RF power supply configured to supply a source RF signal having a first RF frequency to the upper electrode;
a second RF power supply configured to supply a bias RF signal having a second RF frequency to the lower electrode; and
controller circuitry configured to control the substrate processing apparatus to repeat
supply the source RF signal to the upper electrode to generate plasma in the plasma processing chamber in a state in which a magnetic field is generated by the electromagnet in the plasma processing chamber and deposit a deposit on the substrate; and
supply the source RF signal to the upper electrode to generate plasma in the plasma processing chamber in a state in which a magnetic field is generated by the electromagnet in the plasma processing chamber and etch the substrate,
wherein a power level of the source RF signal in the etching the substrate is lower than a power level of the source RF signal in the depositing the deposit on the substrate.

2. The substrate processing apparatus according to claim 1, wherein a power level of the bias RF signal in the etching the substrate is higher than a power level of the bias RF signal in the depositing the deposit on the substrate.

3. The substrate processing apparatus according to claim 2, wherein:
the depositing the deposit on the substrate includes a first period and a second period,
the etching the substrate includes a third period and a fourth period,
the power level of the source RF signal is a first power level in the first period, a second power level in the second period, a third power level in the third period, and a fourth power level in the fourth period, and
the power level of the bias RF signal is a fifth power level in the first period, a sixth power level in the second period, a seventh power level in the third period, and an eighth power level in the fourth period.

4. The substrate processing apparatus according to claim 3, wherein:
the second power level is equal to the first power level,
the third power level is lower than the second power level,
the fourth power level is equal to the third power level,
the sixth power level is higher than the fifth power level,
the seventh power level is higher than the sixth power level, and
the eighth power level is higher than the seventh power level.

5. The substrate processing apparatus according to claim 4, wherein the fifth power level is 0 W.

6. The substrate processing apparatus according to claim 1, wherein currents flowing through radially adjacent coils of the electromagnet are in mutually opposite directions.

7. The substrate processing apparatus according to claim 1, wherein the pressure in the plasma processing chamber is within a range of 1 mTorr to 10 mTorr.

8. The substrate processing apparatus according to claim 1, wherein the pressure in the plasma processing chamber is within a range of 3 mTorr to 8 mTorr.

9. A substrate processing method for a substrate processing apparatus, the substrate processing method comprising:
adjusting a plasma processing chamber in the substrate processing apparatus to a pressure within a range of 1 mTorr to 20 mTorr;
supplying, by a first RF power supply, a source RF signal having a first RF frequency to an upper electrode located above a substrate support supporting a substrate; and
supplying, by a second RF power supply, a bias RF signal having a second RF frequency to a lower electrode of the substrate support;
repeating
supplying the source RF signal to the upper electrode to generate plasma in the plasma processing chamber in a state in which a magnetic field is generated by an electromagnet in the plasma processing chamber and depositing a deposit on the substrate; and
supplying the source RF signal to the upper electrode to generate plasma in the plasma processing chamber in a state in which a magnetic field is generated by the electromagnet in the plasma processing chamber and etching the substrate,
wherein a power level of the source RF signal in the etching the substrate is lower than a power level of the source RF signal in the depositing the deposit on the substrate.

10. The substrate processing apparatus according to claim 2, wherein:
the depositing the deposit on the substrate includes a first period and a second period.

11. The substrate processing apparatus according to claim 2, wherein:
the depositing the deposit on the substrate includes a first period and a second period, and
the etching the substrate includes a third period and a fourth period.

12. The substrate processing apparatus according to claim 2, wherein:
the depositing the deposit on the substrate includes a first period and a second period,
the etching the substrate includes a third period and a fourth period, and
the power level of the source RF signal is a first power level in the first period, a second power level in the second period, a third power level in the third period, and a fourth power level in the fourth period.

13. The substrate processing apparatus according to claim 3, wherein:
the second power level is equal to the first power level.

14. The substrate processing apparatus according to claim 3, wherein:
the second power level is equal to the first power level, and
the third power level is lower than the second power level.

15. The substrate processing apparatus according to claim 3, wherein:
the second power level is equal to the first power level,
the third power level is lower than the second power level, and
the fourth power level is equal to the third power level.

16. The substrate processing apparatus according to claim 3, wherein:
the second power level is equal to the first power level,
the third power level is lower than the second power level,
the fourth power level is equal to the third power level,
the sixth power level is higher than the fifth power level.

17. The substrate processing apparatus according to claim 3, wherein:
the second power level is equal to the first power level,
the third power level is lower than the second power level,
the fourth power level is equal to the third power level,
the sixth power level is higher than the fifth power level, and
the seventh power level is higher than the sixth power level.

18. The substrate processing apparatus according to claim 2, wherein currents flowing through radially adjacent coils of the electromagnet are in mutually opposite directions.

19. A non-transitory computer-readable medium storing executable instructions, which when executed by controller circuitry, causes the controller circuitry to execute a method, the method comprising:
adjusting a plasma processing chamber in a substrate processing apparatus to a pressure within a range of 1 mTorr to 20 mTorr;
supplying, by a first RF power supply, a source RF signal having a first RF frequency to an upper electrode located above a substrate support supporting a substrate; and
supplying, by a second RF power supply, a bias RF signal having a second RF frequency to a lower electrode of the substrate support;
repeating
supplying the source RF signal to the upper electrode to generate plasma in the plasma processing chamber in a state in which a magnetic field is generated by an electromagnet in the plasma processing chamber and depositing a deposit on the substrate; and
supplying the source RF signal to the upper electrode to generate plasma in the plasma processing chamber in a state in which a magnetic field is generated by the electromagnet in the plasma processing chamber and etching the substrate,
wherein a power level of the source RF signal in the etching the substrate is lower than a power level of the source RF signal in the depositing the deposit on the substrate.
